(19) United States
(12) Patent Application Publication
(10) Pub. No.: US 2019/0198632 A1
(43) Pub. Date: Jun. 27, 2019

(54) SEMICONDUCTOR DEVICE AND METHOD OF MANUFACTURING SAME

(71) Applicant: RENESAS ELECTRONICS CORPORATION, Tokyo (JP)

(72) Inventors: Takao KAMOSHIMA, Ibaraki (JP); Mitsuhiro ONUMA, Ibaraki (JP); Hiroaki OSAKA, Ibaraki (JP)

(21) Appl. No.: 16/189,247

(22) Filed: Nov. 13, 2018

(30) Foreign Application Priority Data
Dec. 22, 2017 (JP) 2017-246070

(51) Int. Cl. H01L 29/423; H01L 29/792; H01L 29/66; H01L 29/08; H01L 29/51; H01L 21/28; H01L 21/22; H01L 21/768

(52) U.S. Cl. CPC H01L 29/42344; H01L 29/792; H01L 29/66833; H01L 29/0847; H01L 29/7833; H01L 21/28282; H01L 21/22; H01L 21/76897; H01L 29/517

(57) ABSTRACT

To provide a semiconductor device capable of preventing short circuit between first and second gate electrodes. The semiconductor device has a semiconductor substrate, gate insulating film, first gate electrode, stacked film, and second gate electrode. The semiconductor substrate has a first surface including a first region and a second region adjacent thereto. The gate insulating film is placed on the semiconductor substrate in the first region. The first gate electrode is placed on the gate insulating film and has a side surface. The stacked film has a first oxide film on the second region and on the side surface of the first gate electrode, a nitride film on the first oxide film, and a second oxide film on the nitride film. The second gate electrode is placed on the stacked film in the second region. The side surface above the second gate electrode includes a protrusion toward the side of the second gate electrode.

### CROSS-REFERENCE TO RELATED APPLICATIONS

The disclosure of Japanese Patent Application No. 2017-246070 filed on Dec. 22, 2017 including the specification, drawings and abstract is incorporated herein by reference in its entirety.

### BACKGROUND

The present invention relates to a semiconductor device and a method of manufacturing the same. More specifically, the invention relates to a semiconductor device having a nonvolatile memory element and a method of manufacturing the device.

A semiconductor device having a MONOS (metal oxide nitride oxide semiconductor) transistor as a nonvolatile memory element has conventionally been known. The semiconductor device having a MONOS transistor has a semiconductor substrate having a first surface including a first region and a second region adjacent thereto, a gate insulating film placed on the semiconductor substrate in the first region, a control gate placed on the gate insulating film, an ONO film placed on the second region and the side surface of the control gate, and a word gate placed on the ONO film situated in the second region.

Examples of such a semiconductor device include a semiconductor device described in Patent Document 1 (Japanese Unexamined Patent Application Publication No. 2011-60997).

### PATENT DOCUMENT

[Patent Document 1] Japanese Unexamined Patent Application Publication No. 2011-60997

### SUMMARY

The MONOS transistor is formed by the steps described below. First, a gate insulating film is formed on the first region. Second, a control gate is formed on the gate insulating film. Third, an ONO film is formed to cover the first surface and the control gate. Fourth, a word gate is formed on the ONO film in the second region. Fifth, the ONO film that covers the first surface and the upper surface of the control gate is removed.

During removal of the ONO film that covers the first surface and the upper surface of the control gate, a portion of the ONO film that covers the side surface of the control gate is sometimes removed. Excessive removal of the ONO film that covers the side surface of the control gate may cause short-circuit between the control gate and the word gate when the control gate and the word gate are silicided.

Another problem and a novel feature will be apparent from the description herein and accompanying drawings.

A semiconductor device according to one embodiment has a semiconductor substrate, a gate insulating film, a first gate electrode, a stacked film, and a second gate electrode. The semiconductor substrate has a first surface including a first region and a second region adjacent thereto. The gate insulating film is placed on the semiconductor substrate in the first region. The first gate electrode is placed on the gate insulating film and at the same time, has a side surface. The stacked film has a first oxide film placed on the second region and on the side surface of the first gate electrode, a nitride film placed on the first oxide film, and a second oxide film placed on the nitride film. The second gate electrode is placed on the stacked film in the second region. The side surface present above the second gate electrode includes a protrusion to the side of the second gate electrode.

The semiconductor device according to the one embodiment makes it possible to prevent short-circuit between the first gate electrode and the second gate electrode.

### BRIEF DESCRIPTION OF THE DRAWINGS

FIG. 1 is a schematic layout view of a semiconductor device of First Embodiment;

FIG. 2 is a cross-sectional view of the semiconductor device of First Embodiment;

FIG. 3 is a flow chart showing a method of manufacturing the semiconductor device of First Embodiment;

FIG. 4 is a cross-sectional view of the semiconductor device of First embodiment before a gate insulating film formation step S11 is performed;

FIG. 5 is a cross-sectional view of the semiconductor device of First Embodiment in the gate insulating film formation step S11;

FIG. 6 is a cross-sectional view of the semiconductor device of First Embodiment in a first gate electrode formation step S12;

FIG. 7 is a cross-sectional view of the semiconductor device of First Embodiment in a stacked film formation step S13;

FIG. 8 is a cross-sectional view of the semiconductor device of First Embodiment in a second gate electrode formation step S14;

FIG. 9 is a cross-sectional view of the semiconductor device of First Embodiment in a first impurity implantation step S15;

FIG. 10 is a cross-sectional view of the semiconductor device of First Embodiment in a stacked film removal step S16;

FIG. 11 is a cross-sectional view of the semiconductor device of First Embodiment in a sidewall spacer formation step S17;

FIG. 12 is a cross-sectional view of the semiconductor device of First Embodiment in a second impurity implantation step S18;

FIG. 13 is a cross-sectional view of the semiconductor device of First Embodiment in a silicide film formation step S19;

FIG. 14 is a cross-sectional view of the semiconductor device of First Embodiment in an interlayer insulating film formation step S21;

FIG. 15 is a cross-sectional view of the semiconductor device of First Embodiment in a contact plug formation step S22;

FIG. 16 is a cross-sectional view of a semiconductor device of Comparative Example;

FIG. 17 is a cross-sectional view of a semiconductor device of Second Embodiment;

FIG. 18 is a cross-sectional view of a semiconductor device of Third Embodiment; and

FIG. 19 is a cross-sectional view of a semiconductor device of Fourth Embodiment.

### DETAILED DESCRIPTION

Details of Embodiments will be described referring to the drawings. Same portions or portions corresponding thereto will be identified by the same reference numeral and overlapping description will not be repeated.

### First Embodiment

The semiconductor device of First Embodiment will be described.

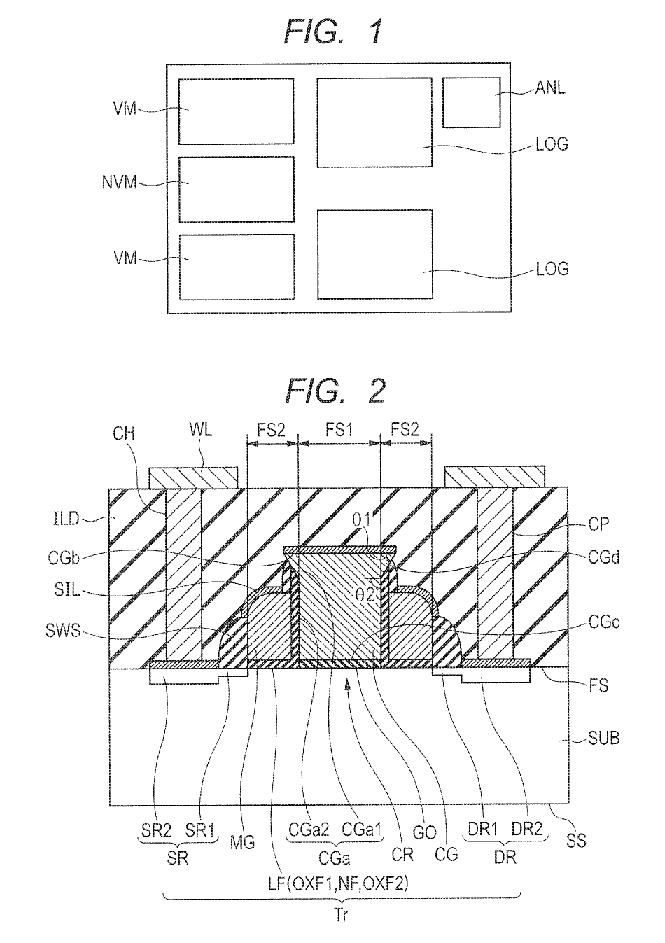

The semiconductor device of First Embodiment is a semiconductor device including a nonvolatile memory element. The semiconductor device of First Embodiment is, for example, a microcontroller. More specifically, the semiconductor device of First Embodiment has, as shown in FIG. 1, a logic circuit LOG, an analog circuit ANL, a volatile memory circuit VM, and a nonvolatile memory circuit NVM. The logic circuit LOG is, for example, CPU (central processing unit). The analog circuit ANL is, for example, an ADC (analog to digital convertor) circuit. The volatile memory circuit VM is, for example, a SRAM (synchronous random access memory) circuit. The nonvolatile memory circuit includes a MONOS transistor Tr.

As shown in FIG. 2, the semiconductor device of First Embodiment has a semiconductor substrate SUB, a gate insulating film GO, a first gate electrode CG, a stacked film LF, a second gate electrode MG, a sidewall spacer SWS, a silicide film SIL, an interlayer insulating film ILD, a contact plug CP, and a wiring layer WL.

The semiconductor substrate SUB is made of, for example, single crystal silicon (Si). The semiconductor substrate SUB has a first surface FS and a second surface SS. The second surface SS is a surface opposite to the first surface FS. The first surface FS and the second surface SS configure the main surface (surface having an area larger than that of the other surface) of the semiconductor substrate SUB.

The semiconductor substrate SUB has a source region SR, a drain region DR, and a channel region CR. The source region SR and the drain region DR each have a first conductivity type. The channel region CR has a second conductivity type. The second conductivity type is a conductivity type opposite to the first conductivity type. For example, when the first conductivity type is an n type, the second conductivity type is a p type.

The source region SR is placed in the first surface FS. The source region SR has a first portion SR1 and a second portion SR2. The second portion SR2 is placed adjacent to the first portion SR1. The first portion SR1 is placed closer to the drain region DR than the second portion SR2 is. The impurity concentration in the first portion SR1 is lower than that in the second portion SR2. This means that the first portion SR1 has a LDD (lightly doped diffusion) structure.

The drain region DR is placed in the first surface FS. The drain region DR is separated from the source region SR. The drain region DR has a first portion DR1 and a second portion DR2. The second portion DR2 is placed adjacent to the first portion DR1. The first portion DR1 is placed closer to the source region SR than the second portion DR2 is. The impurity concentration in the first portion DR1 is lower than that in the second portion DR2. This means that the first portion DR1 has an LDD structure.

The channel region CR is placed on the first surface FS. The channel region CR is sandwiched between the source region SR and the drain region DR.

The first surface FS includes a first region FS1 and a second region FS2. The first region FS1 and the second region FS2 are placed adjacent to each other. The channel region CR is placed in the first surface FS in the first region FS1 and the second region FS2. The first region FS1 is sandwiched between the second region FS2 on the side of the source region SR and the second region FS2 on the side of the drain region DR.

The gate insulating film GO is made of, for example, silicon dioxide (SiO₂). The gate insulating film GO is placed on the semiconductor substrate in the first region FS1.

The first gate electrode CG is made of, for example, impurity-doped polycrystalline Si. The first gate electrode CG is placed on the gate insulating film GO. In other words, the first gate electrode CG faces to the channel region CR, while being insulated therefrom. The first gate electrode CG has a side surface CGa, an upper surface CGb, and a bottom surface CGc. The bottom surface CGc is a surface opposite to the upper surface CGb.

The side surface CGa present above the second gate electrode MG has a protrusion CGd. The protrusion CGd protrudes to the side of the second gate electrode MG.

The side surface CGa includes a first portion CGa1 and a second portion CGa2. The first portion CGa1 is a portion of the side surface CGa continuous to the upper surface CGb. The second portion CGa2 is a portion of the side surface CGa continuous to the first portion CGa1 and also to the bottom surface CGc.

An angle between the first portion CGa1 and the upper surface CGb is an angle θ1. The angle θ1 is less than 90°. A portion of the first gate electrode CG defined by the first portion CGa1 and the upper surface CGb configures a protrusion CGd. An angle between the second portion CGa2 and the upper surface CGb is an angle θ2. The angle θ2 is, for example, 90°.

The stacked film LF is comprised of a first oxide film OXF1, a nitride film NF, and a second oxide film OXF2. The first oxide film OXF1 is placed on a side surface CGa and on a second region FS2. The first oxide film OXF1 is made of, for example, SiO₂.

The nitride film NF is placed on the first oxide film OXF1. The nitride film NF is made of, for example, silicon nitride (Si₃N₄). The second oxide film OXF2 is placed on the nitride film NF. The second oxide film OXF2 is made of, for example, SiO₂.

The second gate electrode MG is placed on the stacked film LF in the second region FS2. The second gate electrode MG is placed to face to the first gate electrode CG via the stacked film LF on the side surface CGa. The second gate electrode MG is made of, for example, impurity-doped polycrystalline Si. The second gate electrode MG has a height lower than that of the first gate electrode CG.

The source region SR, the drain region DR, the channel region CR, the gate insulating film GO, the stacked film LF, the first gate electrode CG, and the second gate electrode MG configure the MONOS transistor Tr.

The sidewall spacer SWS is placed to cover the second gate electrode MG and the side surface CGa situated above the second gate electrode MG. The sidewall spacer SWS that covers the second gate electrode MG has an opening. The sidewall spacer SWS is made of, for example, Si₃N₄.

The silicide film SIL is placed on the upper surface CGb. The silicide film SIL is placed also on the surface of the second gate electrode MG exposed from the opening of the sidewall spacer SWS. The silicide film SIL is also placed on a portion of the first surface FS having therein the source region SR and the drain region DR. The silicide film SIL is made of, for example, a compound of cobalt (Co) and Si.

The interlayer insulating film ILD is placed on the first surface FS. The interlayer insulating film ILD is placed to cover the MONOS transistor Tr. The interlayer insulating film ILD is made of, for example, SiO₂.

The interlayer insulating film ILD has a contact hole CH therein. The contact hole CH penetrates through the interlayer insulating film ILD. The contact hole CH is provided on the source region SR and the drain region DR. Although not shown in FIG. 2, the contact hole CH is also provided on the first gate electrode CG and the second gate electrode MG. From another standpoint, the silicide film SIL is exposed from the contact hole CH.

The contact plug CP is placed in the contact hole CH. The contact plug CP is electrically coupled to the source region SR, the drain region DR, the first gate electrode CG, and the second gate electrode MG via the silicide film SIL. The contact plug CP is made of, for example, tungsten (W).

The wiring layer WL is placed on the interlayer insulating film ILD. The wiring layer WL is electrically coupled to the contact plug CP. This means that the wiring layer WL is electrically coupled to the source region SR, the drain region DR, the first gate electrode CG, and the second gate electrode MG via the contact plug CP and the silicide film SIL. The wiring layer WL is made of, for example, aluminum (Al), Al alloy, copper (Cu), Cu alloy, or the like.

A method of manufacturing the semiconductor device of First Embodiment will be described.

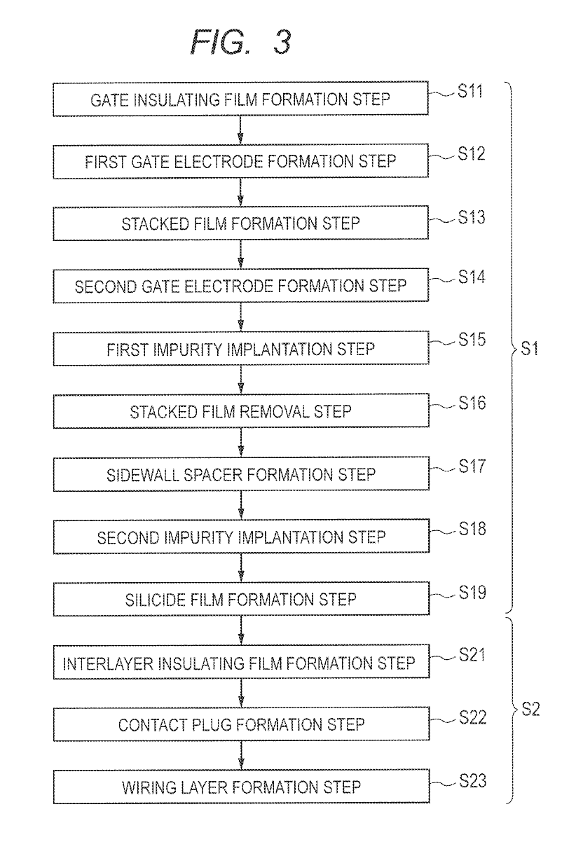

As shown in FIG. 3, the method of manufacturing the semiconductor device of First Embodiment has a front end step S1 and a back end step S2.

The front end step S1 has a gate insulating film formation step S11, a first gate electrode formation step S12, a stacked film formation step S13, a second gate electrode formation step S14, a first impurity implantation step S15, a stacked film removal step S16, a sidewall space formation step S17, a second impurity implantation step S18, and a silicide film formation step S19. The back end step S2 has an interlayer insulating film formation step S21, a contact plug formation step S22, and a wiring layer formation step S23.

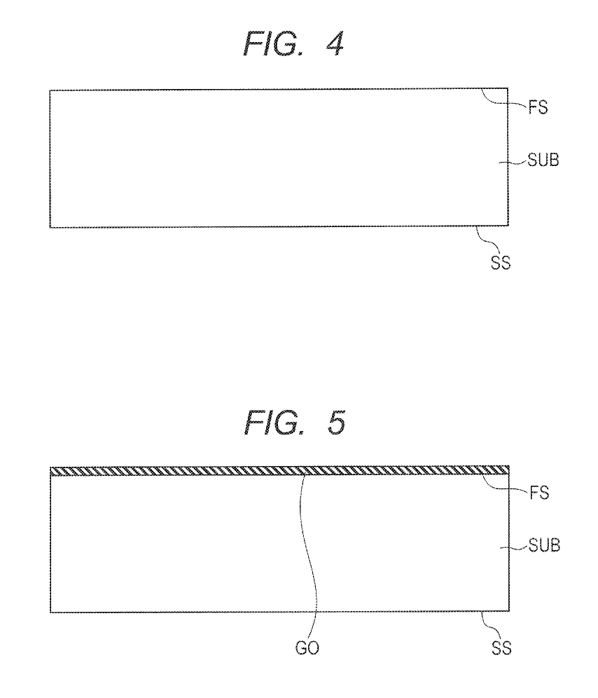

As shown in FIG. 4, a semiconductor substrate SUB having a first surface FS including a first region FS1 and a second region FS2 is provided before the gate insulating film formation step S11. As shown in FIG. 5, in the gate insulating film formation step S11, a gate insulating film GO is formed. The gate insulating film GO is formed, for example, by thermal oxidation of the first surface FS.

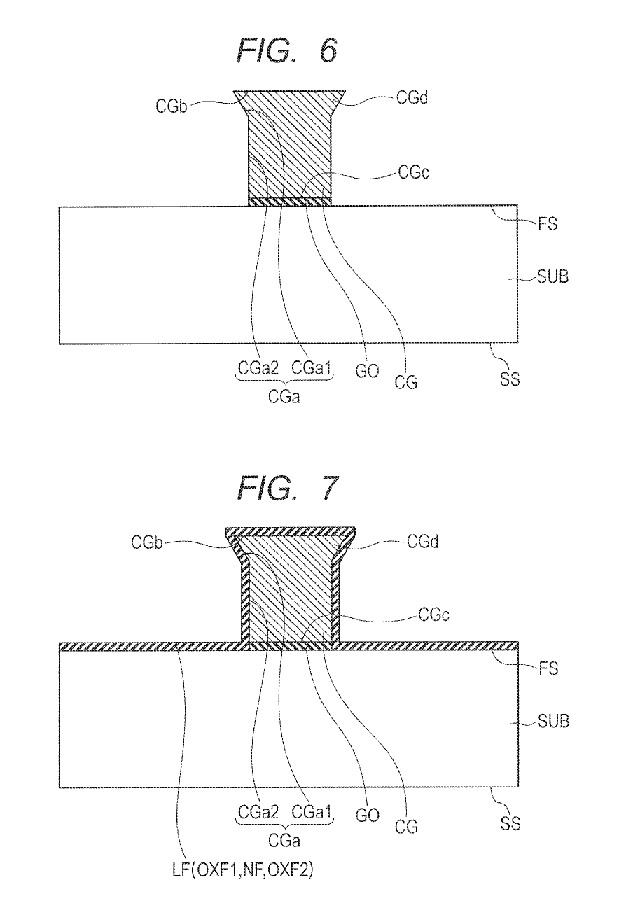

As shown in FIG. 6, in the first gate electrode formation step S12, a first gate electrode CG is formed. In the first gate electrode formation step S12, first, film formation of a material configuring the first gate electrode CG is performed. This film formation is performed, for example, by CVD (chemical vapor deposition).

In the first gate electrode formation step S12, second, a photoresist is applied onto the resulting film made of the material configuring the first gate electrode CG and the photoresist is patterned by photolithography.

In the first gate electrode formation step S12, third, the film made of the material configuring the first gate electrode CG is etched. This etching is performed using the above photoresist as a mask. This etching includes first etching and second etching performed thereafter.

The first etching and the second etching are performed by anisotropic etching such as RIE (reactive ion etching) using, for example, an etching gas containing a fluorocarbon-based reactive gas.

The temperature of the first etching is preferably lower than that of the second etching (the temperature of the second etching is preferably higher than that of the first etching). A fluorine concentration in the etching gas used for the first etching is preferably lower than that in the etching gas used for the second etching (the fluorine concentration in the etching gas used for the second etching is preferably higher than that in the etching gas used for the first etching).

With a decrease in the etching temperature, formation of a polymerization film on the side surface CGa is inhibited more during etching. With a decrease in the fluorine concentration in the etching gas, formation of a polymerization film on the side surface CGa is inhibited more during etching. As the formation of a polymerization film is inhibited more, a ratio of an etching rate in the depth direction to an etching rate in the width direction becomes smaller.

The angle θ1 can therefore be made smaller by setting the temperature of the first etching lower than that of the second etching or by setting the fluorine concentration in the etching gas used for the first etching lower than that in the etching gas used for the second etching.

After formation of the first gate electrode CG, anisotropic etching such as RIE is performed with the first gate electrode CG as a mask to remove the gate insulating film GO on the first surface FS situated in a region other than the first region FS1.

As shown in FIG. 7, in the stacked film formation step S13, a stacked film LF is formed. The stacked film formation step S13 is performed by successive film formation of respective materials configuring a first oxide film OSF1, a nitride film NF, and a second oxide film OXF2 by CVD or the like.

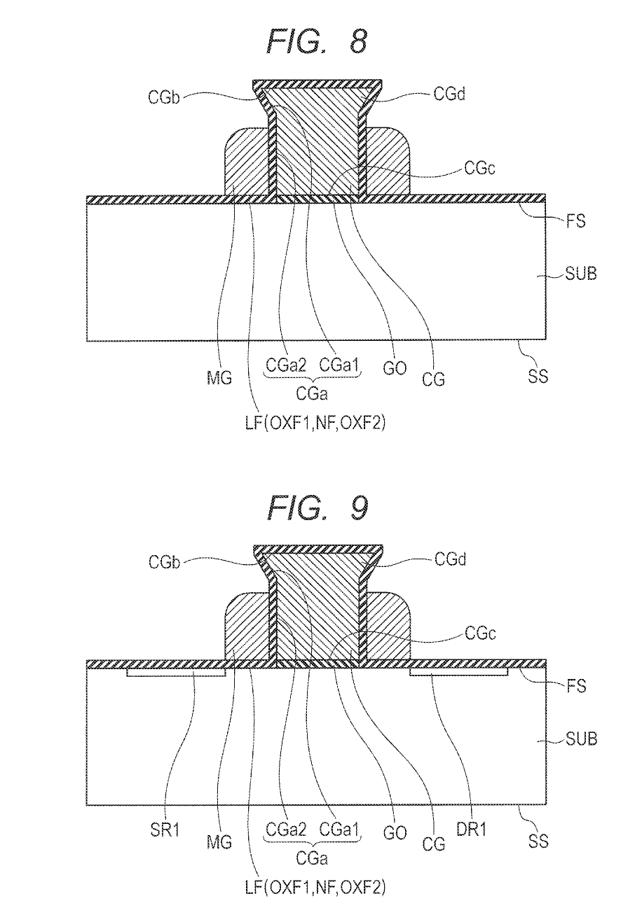

As shown in FIG. 8, in the second gate electrode formation step S14, a second gate electrode MG is formed. In the second gate electrode formation step S14, first, film formation of a material configuring the second gate electrode MG is performed by CVD or the like. In the second gate electrode formation step S14, second, the resulting film made of the material configuring the second gate electrode MG is etched back.

As shown in FIG. 9, in the first impurity implantation step S15, a first portion SR1 and a first portion DR1 are formed. The formation of the first portion SR1 and the first portion DR1 is performed by ion implantation with the first gate electrode CG and the second gate electrode MG as a mask.

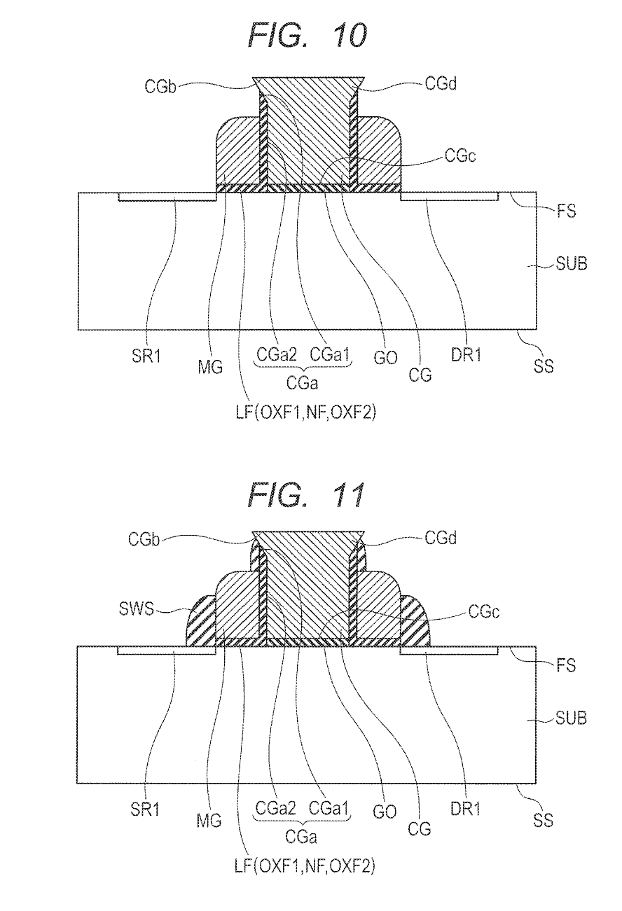

As shown in FIG. 10, in the stacked film removal step S16, the stacked film LF that covers the upper surface CGb is removed. Removal of the stacked film LF that covers the upper surface CGb is performed by anisotropic etching such as RIE.

The material configuring the stacked film LF below the protrusion CGd is hard to remove because the protrusion CGd acts as eaves during anisotropic etching.

As shown in FIG. 11, in the sidewall spacer formation step S17, a sidewall spacer SWS is formed. In the sidewall spacer formation step S17, first, film formation of a material configuring the sidewall spacer SWS is performed. In the sidewall spacer formation step S17, second, the resulting film made of the material configuring the sidewall spacer SWS is etched back.

The material configuring the sidewall spacer SWS below the protrusion CGd is hard to remove because the protrusion CGd acts as eaves during etch back.

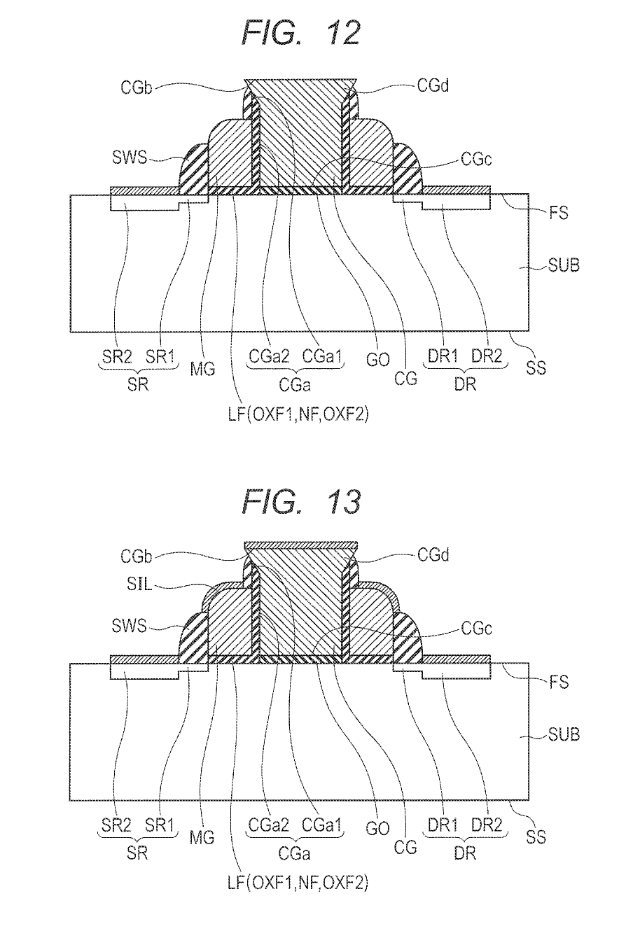

As shown in FIG. 12, in the second impurity implantation step S18, a second portion SR2 and a second portion DR2 are formed. Formation of the second portion SR2 and the second portion DR2 is achieved by ion implantation with the first gate electrode CG, the second gate electrode MG, and the sidewall spacer SWS as a mask.

As shown in FIG. 13, in the silicide film formation step S19, a silicide film SIL is formed. In the silicide film formation step S19, first, formation of a Co film or the like is performed by sputtering or the like. In the silicide film formation step S19, second, heat treatment is performed. By this heat treatment, a reaction occurs between the resulting Co film or the like and Si of the semiconductor substrate SUB, the first gate electrode CG, and the second gate electrode MG which are in contact with the Co film or the like, leading to silicidation. The Co film or the like which has remained without reacting with Si of the semiconductor substrate SUB, the first gate electrode CG, and the second gate electrode MG is removed by etching.

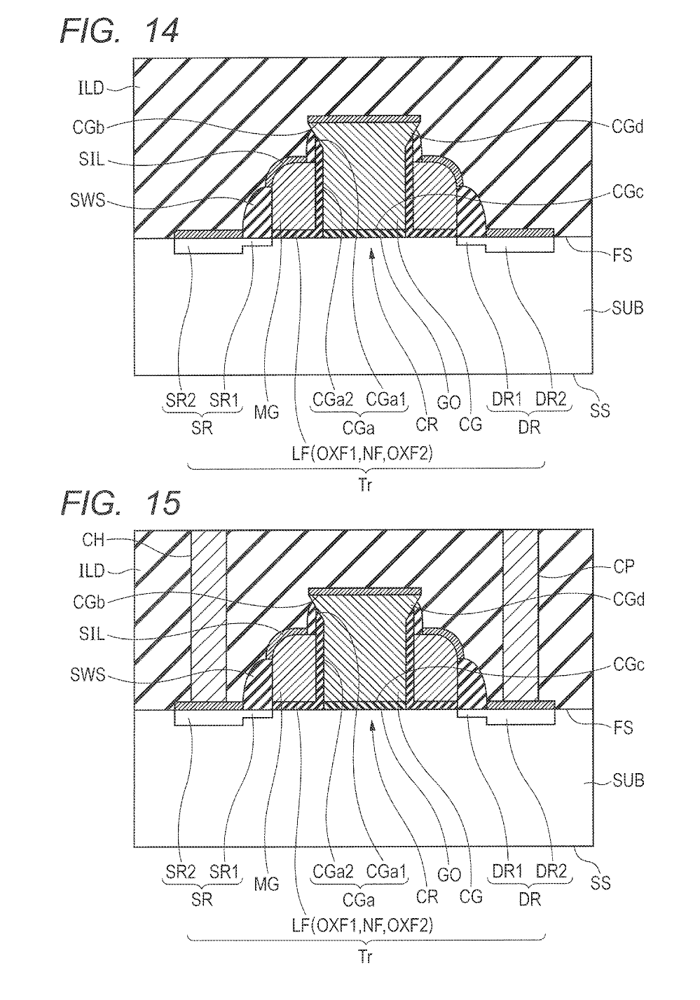

As shown in FIG. 14, in the interlayer insulating film formation step S21, the interlayer insulating film ILD is formed. In the interlayer insulating film formation step S21, first, film formation of a material configuring the interlayer insulating film ILD is performed. In the interlayer insulating film formation step S21, second, planarization is performed to obtain the interlayer insulating film ILD by CMP (chemical mechanical polishing) or the like.

As shown in FIG. 15, in the contact plug formation step S22, the contact plug CP is formed. In the contact plug formation step S22, first, formation of a contact hole CH is performed by anisotropic etching such as RIE. In the contact plug formation step S22, second, the contact hole CH is filled with a material configuring the contact plug CP by CVD or the like. In the contact plug formation step S22, third, the material configuring the contact plug CP and extending out from the contact hole CH is removed by CMP or the like.

In the wiring layer formation step S23, the wiring layer WL is formed. In the wiring layer formation step S23, first, film formation of a material configuring the wiring layer WL is performed by sputtering or the like. In the wiring layer formation step S23, second, the resulting film made of the material configuring the wiring layer WL is patterned by photolithography and etching. By the above-described steps, the structure of the semiconductor device of First Embodiment shown in FIG. 2 is formed.

The advantage of the semiconductor device of First Embodiment will next be described while comparing it with Comparative Example.

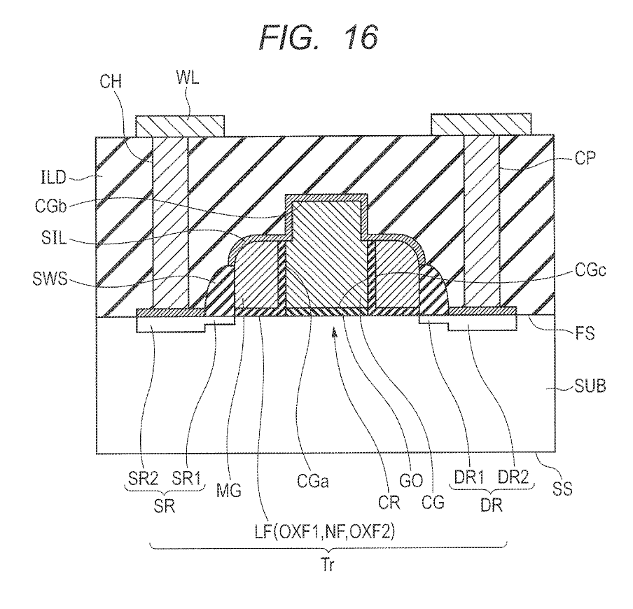

As shown in FIG. 16, the side surface CGa of the semiconductor device of Comparative Example does not have the protrusion CGd. In the semiconductor device of Comparative Example, therefore, a portion of the stacked film LF that covers the side surface CGa present above the second gate electrode MG is easily removed when the stacked film removal step S16 is performed. As a result, in the semiconductor device of Comparative Example, a portion of the side surface CGa present above the second gate electrode MG becomes exposed easily.

If the side surface CGa present above the second gate electrode MG is not covered with the stacked film LF (the side surface CGa present above the second gate electrode MG is exposed), short-circuit may occur between the first gate electrode CG and the second gate electrode MG due to silicidation of the first gate electrode CG and the second gate electrode MG.

In the semiconductor device of First Embodiment, on the other hand, the side surface CGa has the protrusion CGd. The stacked film LF present below the protrusion CGd is hard to remove because the protrusion CGd acts as eaves in the stacked film removal step S16. In other words, in the semiconductor device of First Embodiment, covering of the side surface CGa present above the second gate electrode MG with the stacked film LF can be kept easily.

In the semiconductor device of First Embodiment, since the protrusion CGd serves as eaves during formation of the sidewall spacer SWS, covering of the side surface CGa with the sidewall spacer SWS can be kept easily. In the semiconductor device of First Embodiment, therefore, short-circuit between the first gate electrode CG and the second gate electrode MG can be prevented.

When the angle θ1 between the first portion CGa1 and the upper surface CGb is acute, the protrusion CGd can be formed by controlling the etching conditions for the formation of the first gate electrode CG. In this case, therefore, the semiconductor device of First Embodiment can be manufactured without making a significant change to the manufacturing process.

### Second Embodiment

The configuration of a semiconductor device of Second Embodiment will next be described. A difference from the configuration of the semiconductor device of First Embodiment will be described mainly and an overlapping description will not be repeated.

The semiconductor device of Second Embodiment has a semiconductor substrate SUB, a gate insulating film GO, a first gate electrode CG, a stacked film LF, a second gate electrode MG, a sidewall spacer SWS, a silicide film SIL, an interlayer insulating film ILD, and a wiring layer WL.

The semiconductor substrate SUB has a first surface FS including a first region FS1 and a second region FS2 and a second surface SS. The semiconductor substrate SUB has a source region SR, a drain region DR, and a channel region CR.

The first gate electrode CG has a side surface CGa, an upper surface CGb, and a bottom surface CGc. The side surface CGa includes a protrusion CGd. The side surface CGa has a first portion CGa1 and a second portion CGa2. The stacked film LF has a first oxide film OXF1, a nitride film NF, and a second oxide film OXF2. The above-described points are common to the semiconductor device of Second Embodiment and the semiconductor device of First Embodiment.

The semiconductor device of Second Embodiment is however different from the semiconductor device of First Embodiment in details of the configuration of the side surface CGa.

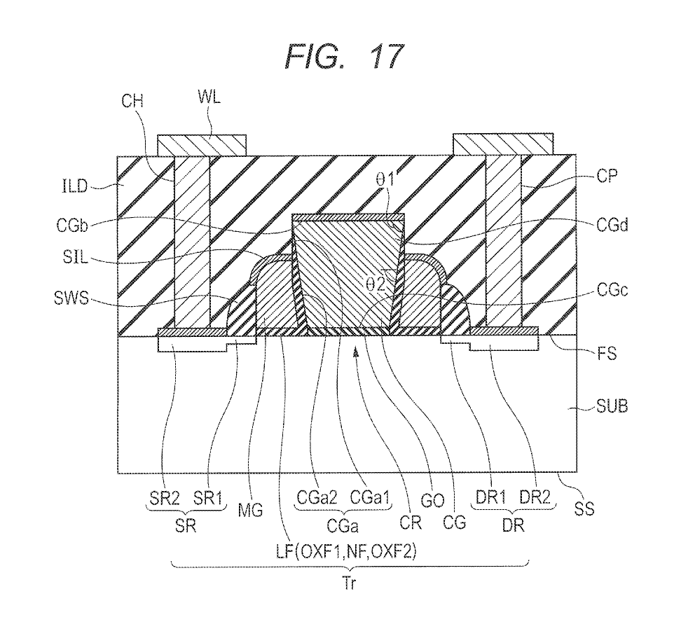

In the semiconductor device of Second Embodiment, the angle θ2 is equal to the angle θ1 as shown in FIG. 17. This means that the side surface CGa situated in the first portion CGa1 is parallel to (flush with) the side surface CGa situated in the second portion CGa2.

A method of manufacturing the semiconductor device of Second Embodiment will next be described. A difference from the method of manufacturing the semiconductor device of First Embodiment will be described mainly and an overlapping description will not be repeated.

The method of manufacturing the semiconductor device of Second Embodiment has a front end step S1 and a back end step S2.

The front end step S1 has a gate insulating film formation step S11, a first gate electrode formation step S12, a stacked film formation step S13, a second gate electrode formation step S14, a first impurity implantation step S15, a stacked film removal step S16, a sidewall spacer formation step S17, a second impurity implantation step S18, and a silicide film formation step S19. The back end step S2 has an interlayer insulating film formation step S21, a contact plug formation step S22, and a wiring layer formation step S23.

The above-described points are common to the method of manufacturing the semiconductor device of Second Embodiment and the method of manufacturing the semiconductor device of First Embodiment. The method of manufacturing the semiconductor device of Second Embodiment is however different from the method of manufacturing the semiconductor device of First Embodiment in details of the first gate electrode formation step S12.

In the method of manufacturing the semiconductor device of Second Embodiment, the first gate electrode formation step S12 is performed without changing etching conditions. This means that the fluorine concentration in an etching gas is constant and an etching temperature is also constant. In the semiconductor device of Second Embodiment, therefore, an inclination angle of the side surface CGa becomes constant (meaning that the angle θ1 and the angle θ2 become equal to each other).

The advantage of the semiconductor device of Second Embodiment will next be described. A difference from the advantage of the semiconductor device of First Embodiment will be described mainly and an overlapping description will not be repeated.

The first gate electrode formation step S12 of the semiconductor device of Second Embodiment is performed without changing the etching conditions. The first gate electrode formation step S12 can therefore performed more simply than that of the semiconductor device of First Embodiment.

### Third Embodiment

The configuration of a semiconductor device of Third Embodiment will be described. A difference from the configuration of the semiconductor device of First Embodiment will be described mainly and an overlapping description will not be repeated.

The semiconductor device of Third Embodiment has a semiconductor substrate SUB, a gate insulating film GO, a first gate electrode CG, a stacked film LF, a second gate electrode MG, a sidewall spacer SWS, a silicide film SIL, an interlayer insulating film ILD, and a wiring layer WL.

The semiconductor substrate SUB has a first surface FS including a first region FS1 and a second region FS2 and a second surface SS. The semiconductor substrate SUB has a source region SR, a drain region DR, and a channel region CR.

The first gate electrode CG has a side surface CGa, an upper surface CGb, and a bottom surface CGc. The side surface CGa includes a protrusion CGd. The side surface CGa has a first portion CGa1 and a second portion CGa2. The stacked film LF has a first oxide film OXF1, a nitride film NF, and a second oxide film OXF2. The above-described points are common to the semiconductor device of Third Embodiment and the semiconductor device of First Embodiment.

The semiconductor device of Third Embodiment is however different from the semiconductor device of First Embodiment in the details of the configuration of the side surface CGa.

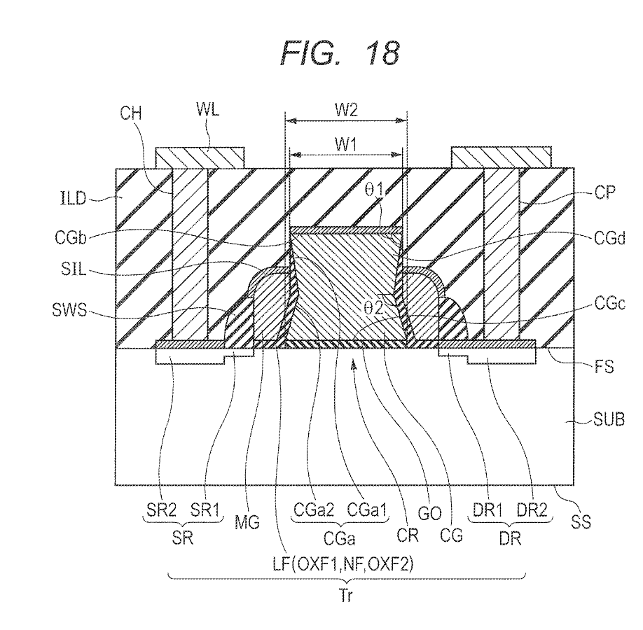

In the semiconductor device of Third Embodiment, the angle θ2 is obtuse as shown in FIG. 18. This means that the angle θ2 is more than 90°. The upper surface CGb has a width W1. The bottom surface CGc has a width W2. The width W2 is preferably greater than the width W1. The width W1 is a width of the upper surface CGb extending in a direction from the source region SR toward the drain region DR. In other words, the width W1 is a width of the upper surface CGb in the channel length direction of the MONOS transistor Tr. The width W2 is a width of the bottom surface CGc in the channel length direction of the MONOS transistor Tr. The width W2 corresponds to the channel length of the MONOS transistor Tr.

The method of manufacturing the semiconductor device of Third Embodiment will be described. A difference from the method of manufacturing the semiconductor device of First Embodiment will be described mainly and an overlapping description will not be repeated.

The method of manufacturing the semiconductor device of Third Embodiment has a front end step S1 and a back end step S2.

The front end step S1 has a gate insulating film formation step S11, a first gate electrode formation step S12, a stacked film formation step S13, a second gate electrode formation step S14, a first impurity implantation step S15, a stacked film removal step S16, a sidewall spacer formation step S17, a second impurity implantation step S18, and a silicide film formation step S19. The back end step S2 has an interlayer insulating film formation step S21, a contact plug formation step S22, and a wiring layer formation step S23.

The above-described points are common to the method of manufacturing the semiconductor device of Third Embodiment and the method of manufacturing the semiconductor device of First Embodiment. The method of manufacturing the semiconductor device of Third Embodiment is however different from the method of manufacturing the semiconductor device of First Embodiment in details of the first gate electrode formation step S12.

In the method of manufacturing the semiconductor device of Third Embodiment, first etching and second etching are performed. A difference in temperature between the first etching and the second etching and a difference in a fluorine concentration between an etching gas used for first etching and an etching gas used for second etching however become larger than those in the method of manufacturing the semiconductor device of First Embodiment. In the semiconductor device of Third Embodiment, therefore, formation of a polymerization film is accelerated in the second etching and the angle θ2 becomes obtuse.

The advantage of the semiconductor device of Third Embodiment will next be described. A difference from the advantage of the semiconductor device of First Embodiment will be described mainly and an overlapping description will not be repeated.

In the manufacturing steps of the semiconductor device of Third Embodiment, the angle θ2 is obtuse and the width W2 is greater than the width W1. When viewed from a direction vertical to the first surface FS, therefore, the end of the bottom surface CGc in the channel length direction is situated outside the end of the upper surface CGb in the channel length direction. When the semiconductor device of Third Embodiment is used, in-line management of the gate length of the MONOS transistor Tr can therefore be achieved by measuring the width W2 by a length measurement SEM (secondary electron microscope) or the like.

### Fourth Embodiment

The configuration of the semiconductor device of Fourth Embodiment will next be described. A difference from the configuration of the semiconductor device of First Embodiment will be described mainly and an overlapping description will not be repeated.

The semiconductor device of Fourth Embodiment has a semiconductor substrate SUB, a gate insulating film GO, a first gate electrode CG, a stacked film LF, a second gate electrode MG, a sidewall spacer SWS, a silicide film SIL, an interlayer insulating film ILD, and a wiring layer WL.

The semiconductor substrate SUB has a first surface FS including a first region FS1 and a second region FS2 and a second surface SS. The semiconductor substrate SUB has a source region SR, a drain region DR, and a channel region CR.

The first gate electrode CG has a side surface CGa, an upper surface CGb, and a bottom surface CGc. The side surface CGa includes a protrusion CGd. The side surface CGa has a first portion CGa1 and a second portion CGa2. The stacked film LF has a first oxide film OXF1, a nitride film NF, and a second oxide film OXF2. The above-described points are common to the semiconductor device of Fourth Embodiment and the semiconductor device of First Embodiment.

The semiconductor device of Fourth Embodiment is however different from the semiconductor device of First Embodiment in details of the structure of the first gate electrode CG.

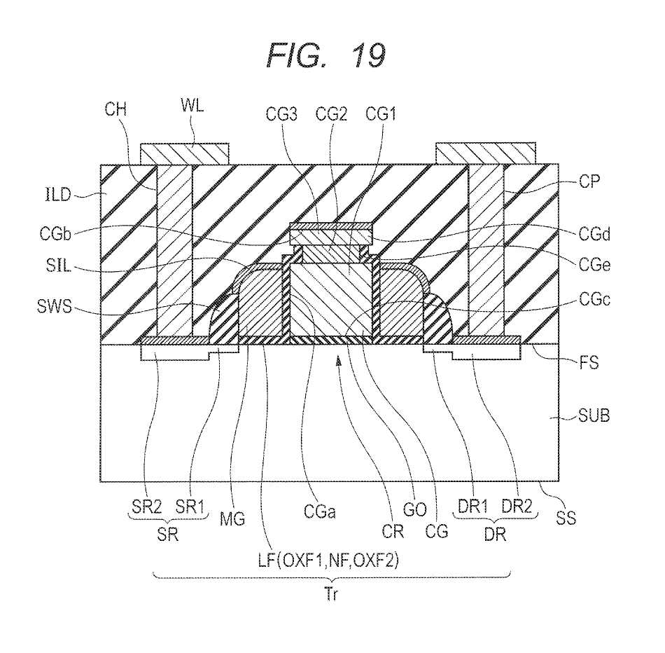

As shown in FIG. 19, the side surface CGa of the semiconductor device of Fourth Embodiment has a recess CGe. In the recess CGe, the side surface CGa is recessed to the side opposite to the second gate electrode MG. The recess CGe is present below the protrusion CGd and above the second gate electrode MG.

The first gate electrode CG may have a first layer CG1, a second layer CG2, and a third layer CG3. The second layer CG2 is placed on the first layer CG1. The third layer CG3 is placed on the gate insulating film GO. The first layer CG1 is placed on the third layer CG3. The side surface CGa situated in the first layer CG1 has the recess CGe.

The etching rate to the first layer CG1 may be higher than the etching rate to the second layer CG2 or the third layer CG3. The first layer CG1 may be made of polycrystalline Si having a higher oxygen concentration than polycrystalline Si configuring the second layer CG2 or the third layer CG3. The first layer CG1 may be made of amorphous Si and the second layer CG2 and the third layer CG3 may be made of polycrystalline Si.

The method of manufacturing the semiconductor device of Fourth Embodiment will next be described. A difference from the method of manufacturing the semiconductor device of First Embodiment will be described mainly and an overlapping description will not be repeated.

The method of manufacturing the semiconductor device of Fourth Embodiment has a front end step S1 and a back end step S2.

The front end step S1 has a gate insulating film formation step S11, a first gate electrode formation step S12, a stacked film formation step S13, a second gate electrode formation step S14, a first impurity implantation step S15, a stacked film removal step S16, a sidewall spacer formation step S17, a second impurity implantation step S18, and a silicide film formation step S19. The back end step S2 has an interlayer insulating film formation step S21, a contact plug formation step S22, and a wiring layer formation step S23.

The above-described points are common to the method of manufacturing the semiconductor device of Fourth Embodiment and the method of manufacturing the semiconductor device of First Embodiment. The method of manufacturing the semiconductor device of Fourth Embodiment is however different from the method of manufacturing the semiconductor device of First Embodiment in details of the first gate electrode formation step S12.

The first gate electrode formation step S12 of the method of manufacturing the semiconductor device of Fourth Embodiment is performed without changing the etching conditions. This means that a fluorine concentration in an etching gas is constant and an etching temperature is also constant. In the method of manufacturing the semiconductor device of Fourth Embodiment, however, the etching rate to the first layer CG1 is higher than that to the second layer CG2 or the third layer CG3 so that the side surface CGa can have the recess CGe.

The advantage of the semiconductor device of Fourth Embodiment will next be described. A difference from the advantage of the semiconductor device of First Embodiment will be described mainly and an overlapping description will not be repeated.

The first gate electrode formation step S12 of the semiconductor device of Fourth Embodiment is performed without changing the etching conditions. The first gate electrode formation step S12 can therefore be made simpler than that for the semiconductor device of First Embodiment.

The invention made by the present inventors has so far been described specifically based on some embodiments. It is needless to say that the present invention is not limited to or by these embodiments but can be modified in various ways without departing from the gist of the invention.

What is claimed is:

1. A semiconductor device, comprising:
a semiconductor substrate having a first surface including a first region and a second region adjacent thereto;
a gate insulating film placed over the semiconductor substrate in the first region;
a first gate electrode placed over the gate insulating film and having a side surface;
a stacked film having a first oxide film placed over the semiconductor substrate in the second region and over the side surface, a nitride film placed over the first oxide film, and a second oxide film placed over the nitride film; and
a second gate electrode placed over the stacked film in the second region,
wherein the side surface present above the second gate electrode includes a protrusion that protrudes toward a side of the second gate electrode.

2. The semiconductor device according to claim 1,
wherein the first gate electrode further has an upper surface,
wherein the side surface includes a first portion continuous to the upper surface, and
wherein an angle between the first portion and the upper surface is less than 90°.

3. The semiconductor device according to claim 2,
wherein the first gate electrode further has a bottom surface which is a surface opposite to the upper surface, and
wherein the side surface and the upper surface make a certain angle from a side of the upper surface to a side of the bottom surface.

4. The semiconductor device according to claim 2,
wherein the first gate electrode further has a bottom surface which is a surface opposite to the upper surface,
wherein the side surface further has a second portion continuous to the first portion and the bottom surface, and
wherein an angle between the second portion and the upper surface is 90° or more.

5. The semiconductor device according to claim 4,
wherein an angle between the second portion and the upper surface is obtuse.

6. The semiconductor device according to claim 5,
wherein the bottom surface has a width greater than that of the upper surface.

7. The semiconductor device according to claim 2,
wherein the stacked film covers the side surface present above the second gate electrode.

8. The semiconductor device according to claim 1, further comprising:
a sidewall spacer placed to cover the second gate electrode and the side surface situated above the second gate electrode.

9. The semiconductor device according to claim 1,
wherein the side surface present above the second gate electrode is situated below the protrusion and includes a recess which is a portion recessed in a direction opposite to the second gate electrode.

10. The semiconductor device according to claim 9,
wherein the second gate electrode has a first layer and a second layer present over the first layer and having an etching rate lower than that of the first layer, and
wherein the recess is made in the first layer.

11. A method of manufacturing a semiconductor device comprising the steps of:
providing a semiconductor substrate having a first surface including a first region and a second region adjacent thereto;
forming a gate insulating film over the semiconductor substrate in the first region;
forming a first gate electrode having a side surface over the gate insulating film;
forming a stacked film having a first oxide film placed over the semiconductor substrate in the second region and the side surface, a nitride film placed over the first oxide film, and a second oxide film placed over the nitride film; and
forming a second gate electrode over the stacked film,
wherein the first gate electrode is formed so that the side surface present above the second gate electrode includes a protrusion toward a side of the second gate electrode.

12. The method of manufacturing a semiconductor device according to claim 11,
wherein the first gate electrode further has an upper surface and a bottom surface which is a surface opposite to the upper surface, and
wherein the side surface includes a first portion continuous to the upper surface and a second portion continuous to the first portion and the bottom surface,
wherein the first gate electrode is formed by first etching and second etching performed thereafter, and
wherein a temperature in the second etching is higher than a temperature in the first etching.

13. The method of manufacturing a semiconductor device according to claim 11,
wherein the first gate electrode further has an upper surface and a bottom surface which is a surface opposite to the upper surface, and
wherein the side surface includes a first portion continuous to the upper surface and a second portion continuous to the first portion and the bottom surface,
wherein the first gate electrode is formed by first etching and second etching performed thereafter, and
wherein a fluorine concentration in an etching gas used for the second etching is lower than a fluorine concentration in an etching gas used for the first etching.
